(19) United States
(12) Patent Application Publication
(10) Pub. No.: US 2025/0227908 A1
(43) Pub. Date: Jul. 10, 2025

(54) STATIC RANDOM ACCESS MEMORY AND METHOD FOR FORMING THE SAME

(71) Applicant: UNITED MICROELECTRONICS CORP., Hsin-Chu City (TW)

(72) Inventors: Chih-Kai Hsu, Tainan City (TW); Chien-Hung Chen, Taipei City (TW); Yu-Hsiang Lin, New Taipei City (TW)

(73) Assignee: UNITED MICROELECTRONICS CORP., Hsin-Chu City (TW)

(21) Appl. No.: 18/430,653

(22) Filed: Feb. 2, 2024

(30) Foreign Application Priority Data
Jan. 4, 2024 (TW) 113100378

(51) Int. Cl. H10B 10/00; H01L 23/528

(52) U.S. Cl. CPC H10B 10/12; H01L 23/5283

(57) ABSTRACT

A static random access memory (SRAM) includes a first active region and a second active region parallel to each other, a first gate structure crossing the first active region and the second active region, a first lower contact and a second lower contact respectively on the first active region and the second active region at a first side of the first gate structure, a third lower contact and a fourth lower contact respectively on the first active region and the second active region at a second side of the first gate structure. An edge of the first lower contact is aligned to an edge of the third lower contact while the other edges are not aligned. An edge of the second lower contact is aligned to an edge of the fourth lower contact while the other edges are not aligned.

### BACKGROUND OF THE INVENTION

### 1. Field of the Invention

The invention relates to a static random access memory (SRAM). More particularly, the invention relates to a SRAM including double-layered contact structures.

### 2. Description of the Prior Art

A static random access memory (SRAM) is a kind of volatile memory, which reserves data in the bit cells when the power is continuously applied and loses data when the power is cut off. Because that SRAM may provide fast access speed and is compatible with the logic device process, it has been widely used as an embedded memory of the processor to be a buffer between the processor and the main memory.

In advanced semiconductor technology, the sizes of SRAM bit cells have been greatly miniaturized to achieve higher integrity. However, the process margin has been more and more critical. A slight process deviation may potentially cause SRAM fail to function properly. Therefore, a novel SRAM design having a larger process margin and a stable product quality is earnestly demanded in the field.

### SUMMARY OF THE INVENTION

In light of the above, the present invention is directed to provide a static random access memory (SRAM) and a method for forming the same, wherein the contact structures on the active regions of the SRAM are respectively composed of an upper contact stacked on a lower contact. The present invention utilizes a multiple patterning process to define the positions and shapes of the lower contacts and introduces proper mismatches between the lower contacts and the upper contacts. In this way, the bottleneck of process development may be improved to increase the process margin.

According to an embodiment of the present invention, a static random access memory is disclosed. The static random access memory includes a substrate including a first active region and a second active region parallel to the first active region, a first gate structure crossing the first active region and the second active region, a first lower contact and a second lower contact respectively on the first active region and the second active region at a first side of the first gate structure, and a third lower contact and a fourth lower contact respectively on the first active region and the second active region at a second side of the first gate structure, wherein in a top view, the first lower contact, the second lower contact, the third lower contact and the fourth lower contact respectively have a first edge between the first active region and the second active region and a second edge opposite to the first edge, wherein the first edge of the first lower contact is aligned to the first edge of the third lower contact, the first edge of the second lower contact is aligned to the first edge of the fourth lower contact, the second edge of the first lower contact is not aligned to the second edge of the third lower contact, and the second edge of the second lower contact is not aligned to the second edge of the fourth lower contact.

According to another embodiment of the present invention, a method for forming a static random access memory is disclosed, which includes the steps of providing a substrate comprising a plurality of active regions arranged parallel to each other, forming a lower interlayer dielectric layer on the substrate and a plurality of gate structures in the lower interlayer dielectric layer and crossing the active regions, forming a first patterned mask on the lower interlayer dielectric layer, the first patterned mask comprising a plurality of slot openings corresponding to the active regions, forming a second patterned mask on the first patterned mask, the second patterned mask comprising a plurality of stripe patterns corresponding to the gate structures, using the first patterned mask and the stripe patterns as an etching mask to etch the lower interlayer dielectric layer, thereby forming a plurality of lower contact openings that expose portions of the active regions, and forming lower contacts in the lower contact openings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a circuit diagram of a bit cell of a static random access memory according to one embodiment of the present invention.

FIG. 2 shows a plane view of a bit cell of a static random access memory according to one embodiment of the present invention.

FIG. 3 shows a cross-sectional view of the static random access memory along line AA′ in FIG. 2.

FIG. 4 shows a cross-sectional view of the static random access memory along line BB′ in FIG. 2.

FIG. 5 to FIG. 14 are schematic drawings illustrating steps of manufacturing a static random access memory according to one embodiment of the present invention, wherein FIG. 5, FIG. 7, FIG. 8, FIG. 11 and FIG. 13 are plane views, and FIG. 6, FIG. 9, FIG. 10, FIG. 12 and FIG. 14 are cross-sectional views along line FF′ in the associated plane views.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

In order to make those of ordinary skilled in the art readily understand the invention and for simplifying the drawings, several drawings in this disclosure only depict a part of the semiconductor structure, and specific elements in the drawings are not drawn to actual scale. In addition, the number and size of each element in the drawings are only for illustration and are not used to limit the scope of the disclosure. It is understood by those of ordinary in the art that the expressions “on”, “above”, “below”, “upper”, “lower”, “over”, “under”, etc. are used for indicating relative positions of the elements, and all the elements can be turned over while still presenting the same structure. Both configurations should belong to the scope disclosed in this specification.

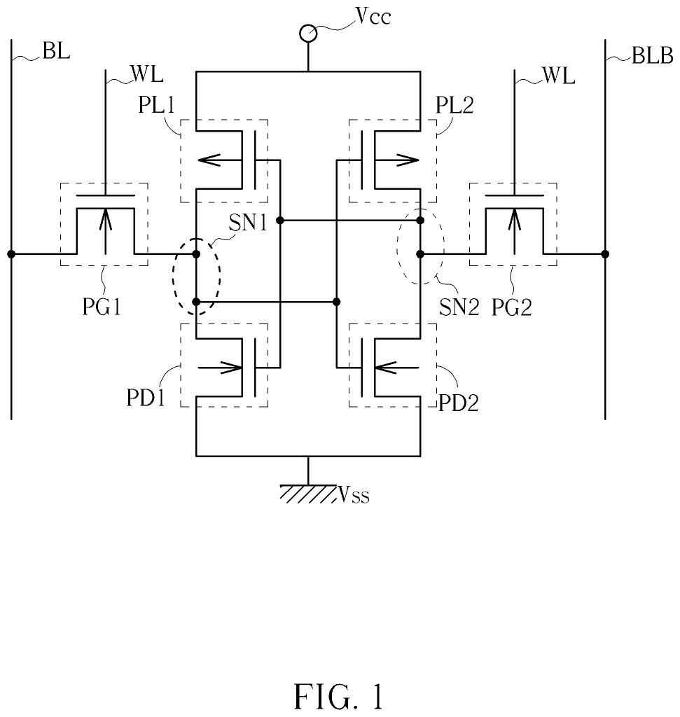

Please refer to FIG. 1, which is a circuit diagram of a bit cell of a static random access memory (SRAM) according to one embodiment of the present invention. The bit cell of the SRAM includes six transistors, and therefore the SRAM may be referred to as a 6T-SRAM. Specifically speaking, the bit cell includes a first pull-up transistor PL1, a second pull-up transistor PL2, a first pull-down transistor PD1, a second pull-down transistor PD2, a first access transistor PG1 and a second access transistor PG2. The first pull-up transistor PL1 and the second pull-up transistor PL2 have a same conductivity type that is complementary to the conductivity type of the first pull-down transistor PD1 and the second pull-down transistor PD2.

The source terminal of the first pull-up transistor PL1 is connected to a power supply voltage Vcc. The drain terminal of the first pull-up transistor PL1 is connected to the drain terminal of the first pull-down transistor PD1. The source terminal of the first pull-down transistor PD1 is connected to a ground voltage Vss. The gate terminal of the first pull-up transistor PL1 and the gate terminal of the first pull-down transistor PD1 are electrically connected to form an inverter. Likewise, the source terminal of the second pull-up transistor PL2 is electrically connected to the power supply voltage Vcc. The drain terminal of the second pull-up transistor PL2 is electrically connected to the drain terminal of the second pull-down transistor PD2. The source terminal of the second pull-down transistor PD2 is electrically connected to the ground voltage Vss. The gate terminal of the second pull-up transistor PL2 and the gate terminal of the second pull-down transistor PD2 are electrically connected to form another inverter. The two inverters are cross-coupled to form a latch circuit by having the gate terminals of the first pull-up transistor PL1 and the first pull-down transistor PD1 electrically connected to the drain terminals of the second pull-up transistor PL2 and the second pull-down transistor PD2, and having the gate terminals of the second pull-up transistor PL2 and the second pull-down transistor PD2 electrically connected to the drain terminals of the first pull-up transistor PL1 and the first pull-down transistor PD1. In this way, the data may be stored in the storage node SN1 or the storage node SN2 of the latch circuit. The first access transistor PG1 and the second access transistor PG2 are used to control the writing and reading of data in the bit cell. The first access transistor PG1 is electrically connected between the storage node SN1 and the bit line BL. The second access transistor PG2 is electrically connected between the storage node SN2 and the complementary bit line BLB. The gate terminals of the first access transistor PG1 and the second access transistor PG2 are electrically connected to the word line WL and the channels of the first access transistor PG1 and the second access transistor PG2 may be turned on or turned off by controlling the word line WL. When the first access transistor PG1 and the second access transistor PG2 are turned on, the bit line BL and the bit line BLB are allowed to write or read data.

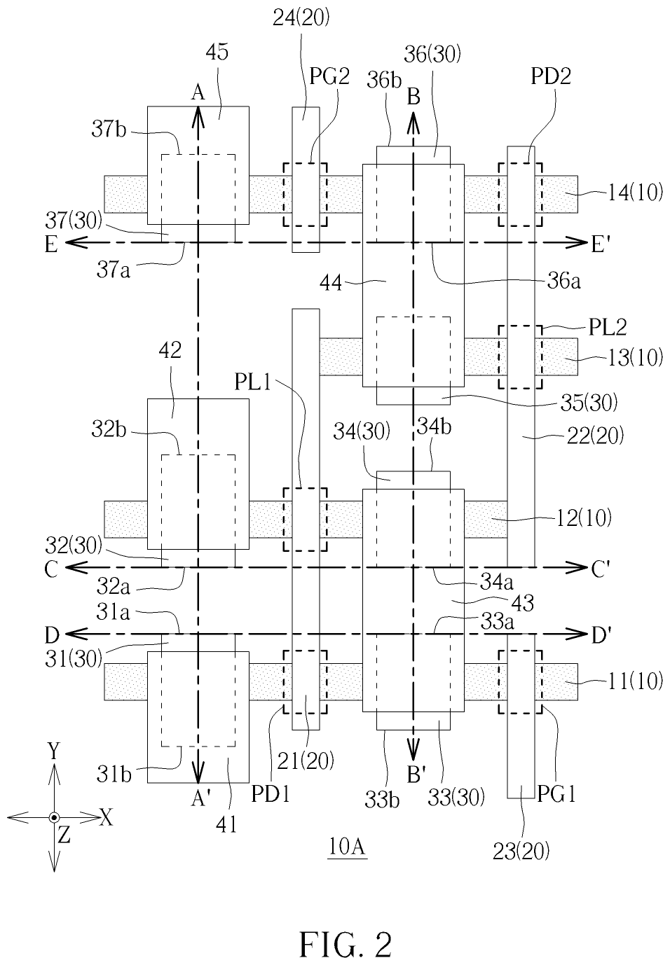

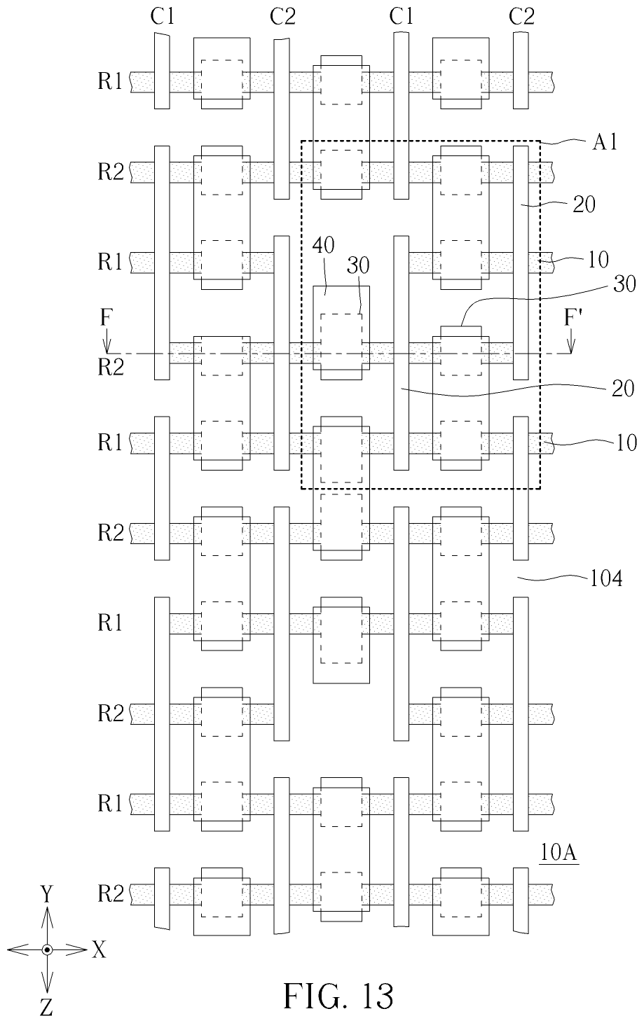

Please refer to FIG. 2 and FIG. 13. FIG. 13 is a partial plane view of a SRAM according to one embodiment of the present invention. FIG. 2 is an enlarged view of the region Al shown in FIG. 13, showing a plane view of a bit cell of the SRAM. The first direction X and the second direction Y shown in the drawings are parallel to the surface of the substrate 10A of the SRAM. The first direction X and the second direction Y are perpendicular to each other. The third direction Z is perpendicular to the surface of the substrate 10A. Lines Aa′ and BB′ are parallel to the second direction Y Lines CC′, DD′ EE′ and FF′ are parallel to the first direction X.

The SRAM is composed of a plurality of the 6T bit cell shown in FIG. 2. The SRAM includes a substrate 10A, and a plurality of active regions 10 and a plurality of gate structures 20 arranged on the substrate 10A. The active regions 10 respectively extend along the first direction X and are parallel to the second direction Y The gate structures 20 respectively extend along the second direction Y, stride across the active regions 10, and are parallel to the first direction X. A plurality of lower contacts 30 are arranged on the substrate 10A and crossing parts of the active regions 10. A plurality of upper contacts 40 are respectively disposed on the lower contacts 30.

As shown in FIG. 2, the bit cell of the SRAM includes a first active region 11, a second active region 12, a third active region 13, and a fourth active region 14 that are arranged next to each other. The second active region 12 is between the first active region 11 and the third active region 13. The third active region 13 is between the second active region 12 and the fourth active region 14. A first gate structure 21 extends across the first active region 11 and the second active region 12 to form the first pull-down transistor PD1 and the first pull-up transistor PL1. A second gate structure 22 extends across the third active region 13 and the fourth active region 14 to form the second pull-down transistor PD2 and the second pull-up transistor PL2. The first gate structure 21 and the second gate structure 22 are adjacent to each other in a staggered manner. In one embodiment of the present invention, the first pull-up transistor PL1 and the second pull-up transistor PL2 are p-type metal-oxide-semiconductor (PMOS) transistors. The first pull-down transistor PD1 and the second pull-down transistor PD2 are n-type metal-oxide-semiconductor (NMOS) transistors.

A first lower contact 31 is disposed on the first active region 11 at a side of the first gate structure 21. A first upper contact 41 is disposed on the first lower contact 31. The first lower contact 31 and the first upper contact 41 are electrically connected to connect the source terminal of the first pull-down transistor PD1 to the ground voltage Vss. A second lower contact 32 is disposed on the second active region 12 at the same side as the first lower contact 31. A second upper contact 42 is disposed on the second lower contact 32. The second lower contact 32 and the second upper contact 42 are electrically connected to connect the source terminal of the first pull-up transistor PL1 to the power supply voltage Vcc.

A third lower contact 33 and a fourth lower contact 34 are respectively disposed on the first active region 11 and the second active region 12 at the other side of the first gate structure 21. A third upper contact 43 is disposed on and electrically connect the third lower contact 33 and the fourth lower contact 34, so that the drain terminal of the first pull-up transistor PL1 and the drain terminal of the first pull-down transistor PD1 are electrically connected.

A fifth lower contact 35 and a sixth lower contact 36 are respectively disposed on the third active region 13 and the fourth active region 14 at a side of the second gate structure 22 next to the first gate structure 21. A fourth upper contact 44 is disposed on and electrically connect the fifth lower contact 35 and the sixth lower contact 36, so that the drain terminal of the second pull-up transistor PL2 and the drain terminal of the second pull-down transistor PD2 are electrically connected.

An end portion of the first gate structure 21 extends to overlap and electrically connect with an end portion of the third active region 13. An end portion of the second gate structure 22 extends to overlap and electrically connect with an end portion of the second active region 12. Accordingly, the inverter formed by the first pull-up transistor PL1 and the first pull-down transistor PD1 and the inverter formed by the second pull-up transistor PL2 and the second pull-down transistor PD2 are interconnected to form a latch circuit.

A first access gate structure 23 which is aligned with the second gate structure 22 along the second direction Y strides across the first active region 11 to form the first access transistor PG1. A second access gate structure 24 which is aligned with the first gate structure 21 along the second direction Y strides across the fourth active region 14 to form the second access transistor PG2. In one embodiment of the present invention, the first access transistor PG1 and the second access transistor PG2 are n-type metal-oxide-semiconductor (NMOS) transistors. As shown in FIG. 2, a seventh lower contact 37 is disposed on the fourth active region 14 at a side of the second access transistor PG2 opposite to the sixth lower contact 36, and a fifth upper contact 45 is disposed on the seventh lower contact 37. The seventh lower contact 37 and the fifth upper contact 45 are electrically connected to connect the second access transistor PG2 to the bit line BLB (as shown in FIG. 1). Another contact structure (not shown) may be disposed on the first active region 11 at a side of the first access transistor PG1 opposite to the third lower contact 33 to electrically connect the first access transistor PG1 to the bit line BL.

The contact structures of the present invention are respectively composed of a lower contact and an upper contact, so that the layout flexibility may be increased. Additionally, process margin may be improved by employing proper mismatches between the lower contacts and the upper contacts, so that problems such as short circuit leakage caused by insufficient spacing between upper contacts may be prevented. Furthermore, the present invention utilizes a multiple patterning process to form the contact structures, as described below, may help obtain the desired position and shape of the lower contact.

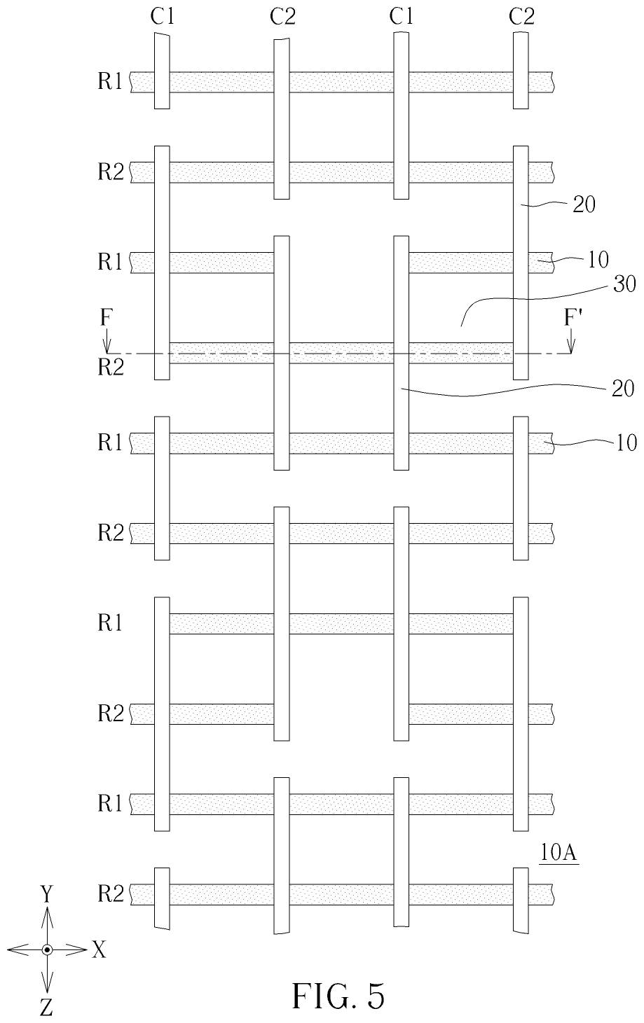

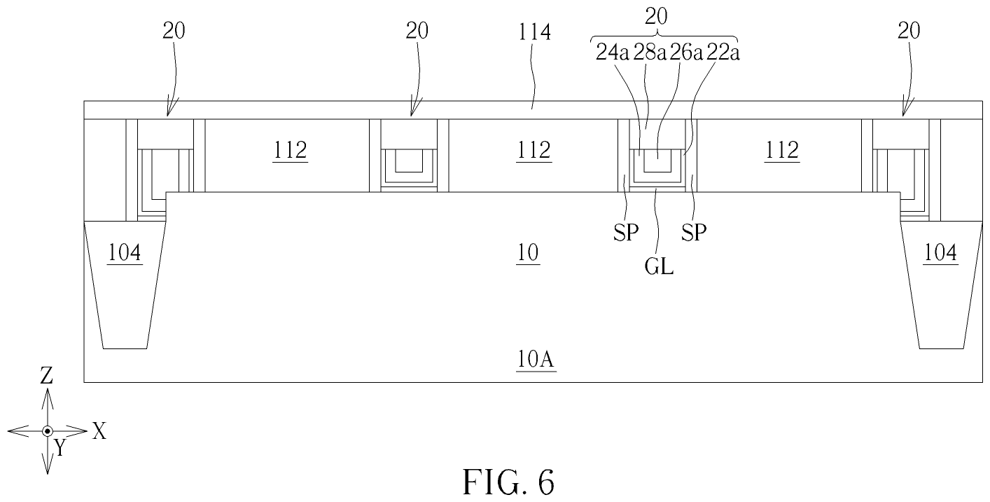

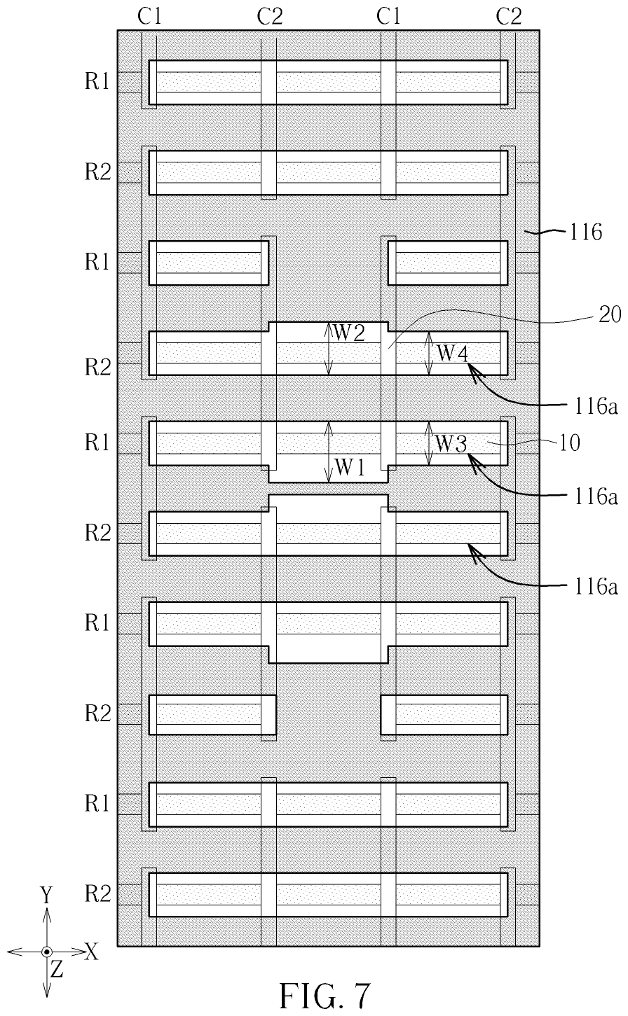

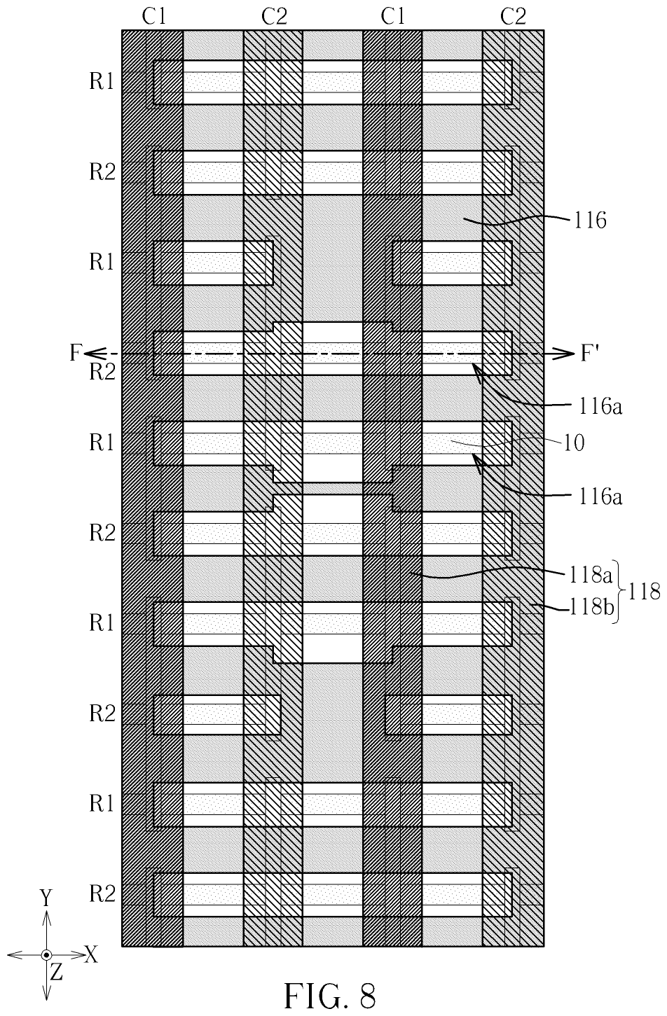

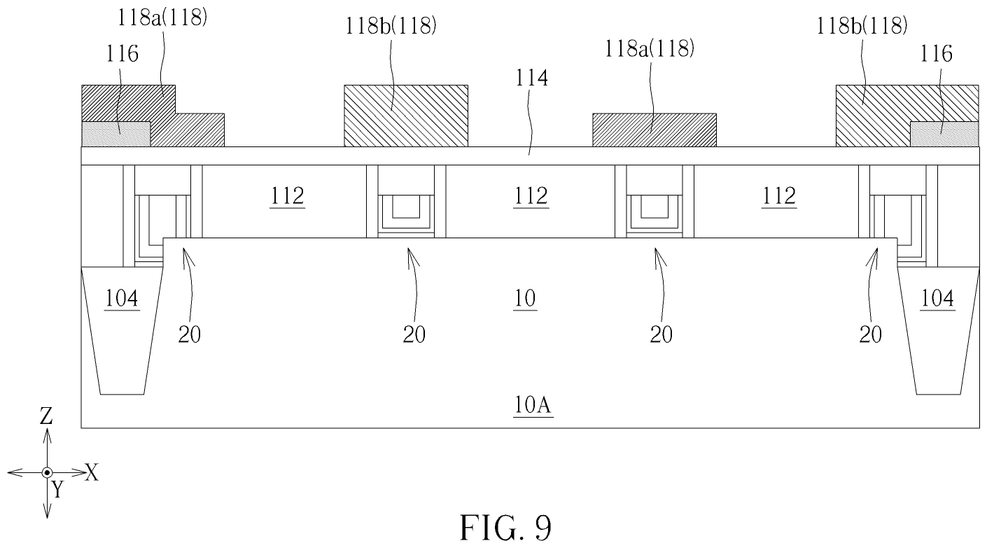

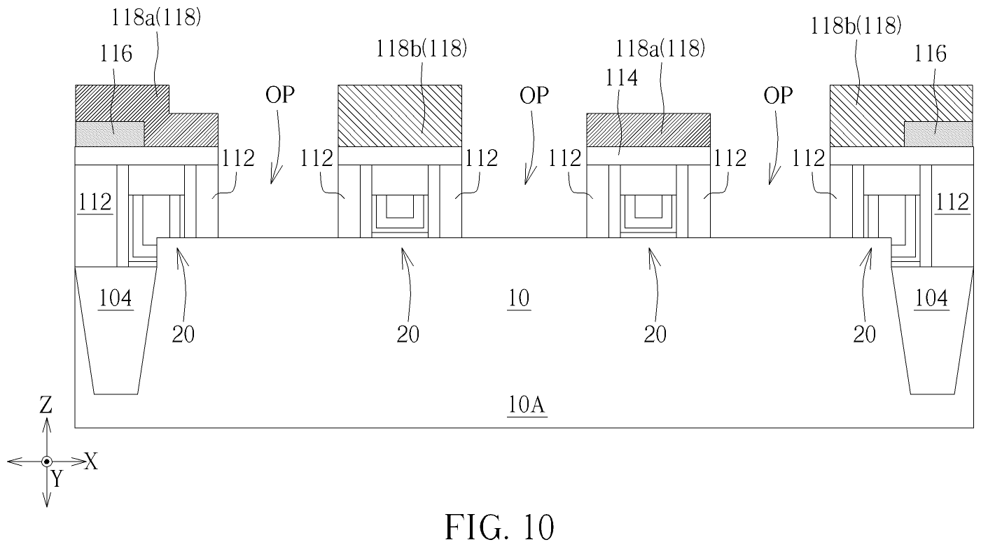

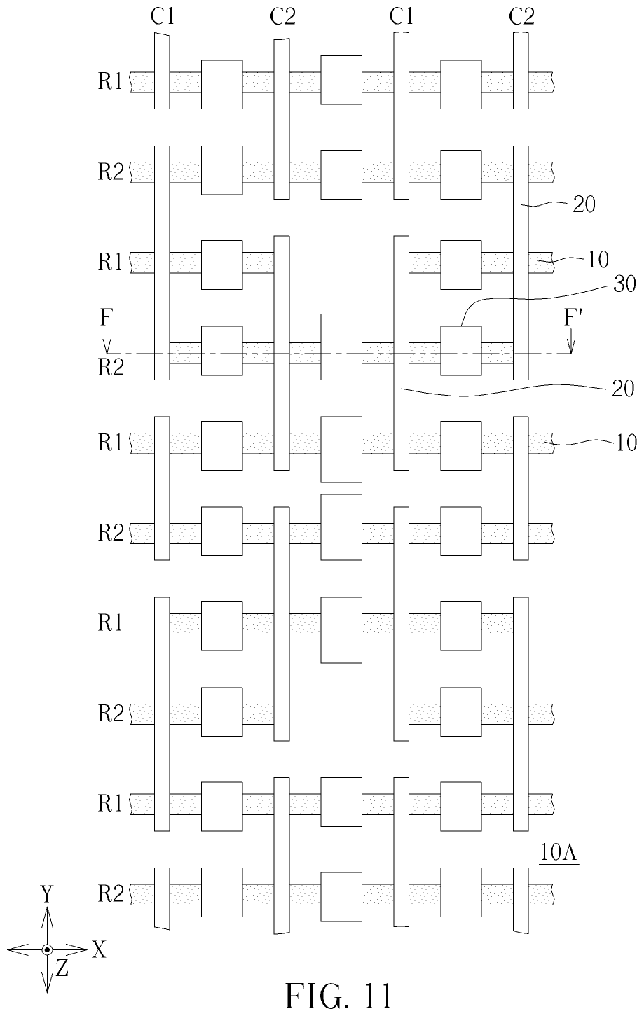

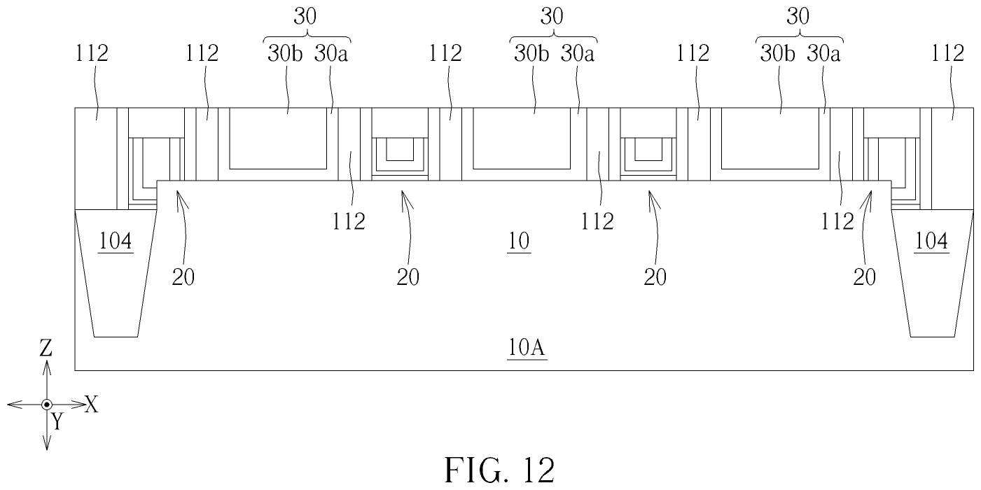

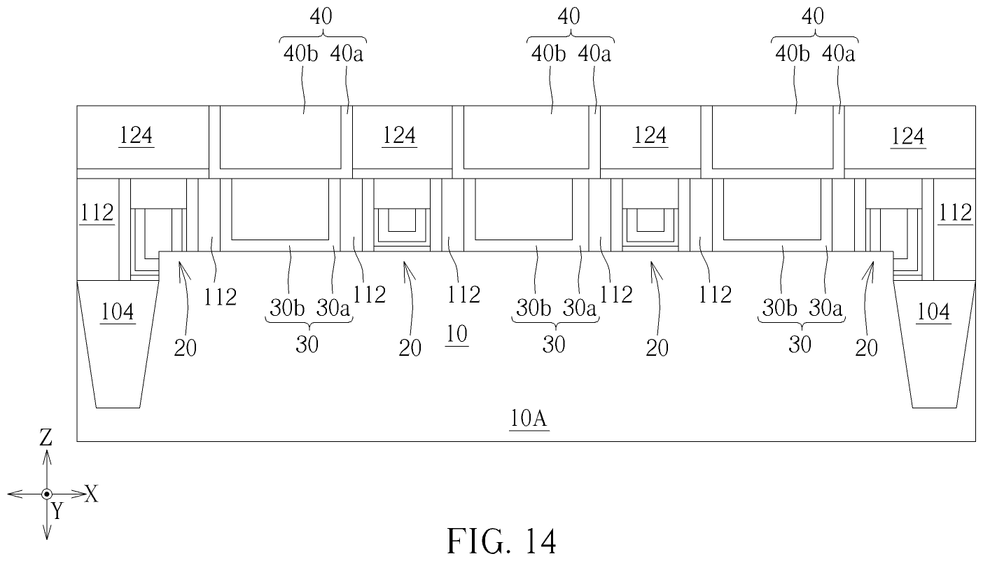

Please refer to FIG. 5 to FIG. 14, which are schematic drawings illustrating steps of manufacturing a static random access memory according to one embodiment of the present invention, wherein FIG. 5, FIG. 7, FIG. 8, FIG. 11 and FIG. 13 are plane views, and FIG. 6, FIG. 9, FIG. 10, FIG. 12 and FIG. 14 are cross-sectional views along line FF′ in the associated plane views. For simplicity, certain components may be omitted in the plan and sectional views.

As shown in FIG. 5 and FIG. 6, a substrate 10A is provided. The substrate 10A includes a plurality of active regions 10. The active regions 10 respectively extend along the first direction X and arranged parallel to the second direction Y, and are separated from each other by an isolation structure 104. The substrate 10A may be a silicon substrate, silicon-on-insulator (SOI) substrate, or III-V semiconductor substrate, but is not limited thereto. The active regions 10 may be fin structures formed by patterning the substrate 10A, or by performing a selective epitaxial growing process, but is not limited thereto. The isolation structure may be shallow trench isolation (STI), but is not limited thereto. Following, a lower dielectric layer 112 and gate structures 20 in the lower dielectric layer 112 are formed on the substrate 10A. Subsequently, a buffer layer 114 is formed on the lower dielectric layer 112 and gate structures 20. The gate structures 20 extend along the second direction Y, striding across the active regions 10, and are parallel and staggered to each other along the first direction X. The gate structures 20 may be metal gates, respectively including a gate dielectric layer 22a, a work function metal layer 24a on the gate dielectric layer 22a, a low-resistance metal layer 26a on the work function metal layer 24a, and a capping layer 28a on the low-resistance metal layer 26a. The top surfaces of the capping layers 28a of the gate structures 20 are flush with the top surface of the lower dielectric layer 112. In some embodiments, an interface layer GL may be formed between the bottom surfaces of the gate structures 20 and the substrate 10A. Spacers SP may be formed between the sidewalls of the gate structures 20 and the lower dielectric layer 112, and the top surfaces of the spacers SP are flush with the top surface of the lower dielectric layer 112. In some embodiments, an etching stop layer or a stressor layer (not shown in the diagram) may be formed between the lower dielectric layer 112 and the substrate 10A. For the ease of illustration, R1 and R2 in the drawings refer to odd rows and even rows of the active areas 10. C1 and C2 in the drawings refer to odd columns and even columns of the active areas 10.

Subsequently, as shown in FIG. 7, a first mask layer 116 is formed on the buffer layer 114. A patterning process is performed to the first mask layer 116 to define multiple slot openings 116a in the first mask layer 116. The slot openings 116a respectively have a length along the first direction X and corresponding to the active regions 10. In one embodiment of the present invention, the slot openings 116a are formed through a double patterning process, which includes the step of using a first photo mask (not shown) in a photolithography-etching process to define the slot openings 116a corresponding to active regions 10 of the odd rows R1, and using a second photo mask (not shown) in another photolithography-etching process to define the slot openings 116a corresponding to active regions 10 of the even rows R2.

It is noteworthy that the slot openings 116a at different positions may have different shapes and sizes. Please refer to FIG. 7 and FIG. 2. The first lower contact 31 and the third lower contact 33 are defined by a same slot opening 116a that is T-shaped. The second lower contact 32 and the fourth lower contact 34 are defined by a same slot opening 116a that is T-shaped. The sixth lower contact 36 and the seventh lower contact 37 are defined by a same slot opening 116a that has linear shape. The width W1 and width W2 of the portions of the slot openings 116a corresponding to the first lower contact 31 and the second lower contact 32 are larger than the width W3 and width W4 of the portions of the slop openings 116a corresponding to the third lower contact 33 and the fourth lower contact 34. In some embodiments, the width W1 and the width W2 are the same, and the width W3 and the width W4 are the same. In some embodiments, the widths of the portions of the slot openings 116a corresponding to the fifth lower contact 35, the sixth lower contact 36, and the seventh lower contact 37 may be equal to the width W3 or the width W4. In one embodiment, the material of the first mask layer 116 is titanium nitride (TiN), but it is not limited thereto.

Please refer to FIG. 8 and FIG. 9. Subsequently, a second mask layer 118 is formed on the first mask layer 116. The second mask layer 118 includes a plurality of stripe patterns 118a and 118b which respectively extend along the second direction Y and are alternately arranged along the first direction X. The stripe patterns 118a correspond to the gate structures 20 of the odd columns C1. The stripe patterns 118b correspond to the gate structures 20 of the even columns C2. In one embodiment of the present invention, the material of the stripe patterns 118a is different from the material of the stripe patterns 118b. The method to form the stripe patterns 118a and 118b may include the following steps. First, a first material layer (not shown) is formed on the first mask layer 116. A photolithography-etching process using a third photo mask (not shown) is performed to pattern the first material layer into the stripe patterns 118a. Following, a second material layer (not shown) is formed on the first mask layer 116 and covering the stripe patterns 118a, and another photolithography-etching process using a fourth photo mask (not shown) is performed to pattern the second material layer into the stripe patterns 118b. In one embodiment of the present invention, the material of the stripe patterns 118a is silicon nitride (SiN), and the material of the stripe patterns 118b is photoresist, but is not limited thereto.

Please refer to FIG. 10. Subsequently, an etching process using the first mask layer 116 and the second mask layer 118 as an etching mask is performed to etch the buffer layer 114 and the lower dielectric layer 112 exposed from spaces between the stripe patterns 118a and 118b and the slot openings 116a, thereby forming a plurality of lower contact openings OP that expose portions of the active regions 10.

Please refer to FIG. 11 and FIG. 12. After removing the first mask layer 116 and the second mask layer 118, a barrier layer 30a is formed along the sidewalls and bottom surfaces of the lower contact openings OP. Subsequently, a conductive material 30b is formed on the substrate 10A to fill the lower contact openings OP. A planarization process (such as a chemical-mechanical polishing process) may be used to remove the redundant parts of the barrier layer 30a, the conductive material 30b, and the buffer layer 114 outside the lower contact openings OP until exposing the top surfaces (the surfaces of the capping layer 28a) of the gate structures 20, thereby obtaining the lower contacts 30. As shown in FIG. 12, the top surfaces of the lower contacts 30 are flush with the top surfaces of the gate structure 20 and the top surface of the lower dielectric layer 112.

Please refer to FIG. 13 and FIG. 14. An etching stop layer 122 and an upper dielectric layer 124 are formed on the lower dielectric layer 112. A patterning process such as a photolithography-etching process is performed to form a plurality of upper contact openings (not shown) that vertically extend through the upper dielectric layer 124 and the etching stop layer 122 and expose portions of the lower contacts 30. A barrier layer 40a and a conductive material 40b are then formed to fill the upper contact openings, thereby obtaining the upper contacts 40. In some embodiments, gate contact openings (not shown) may be defined in the upper dielectric layer 124 and the etching stop layer 122 by the same patterning process for forming the upper contact openings, and gate contact structures (not shown) which are electrically connected with the gate structures 20 may be formed in the gate contact openings by the same process for forming the upper contacts 40. After completing the step, the SRAM of the present invention is obtained.

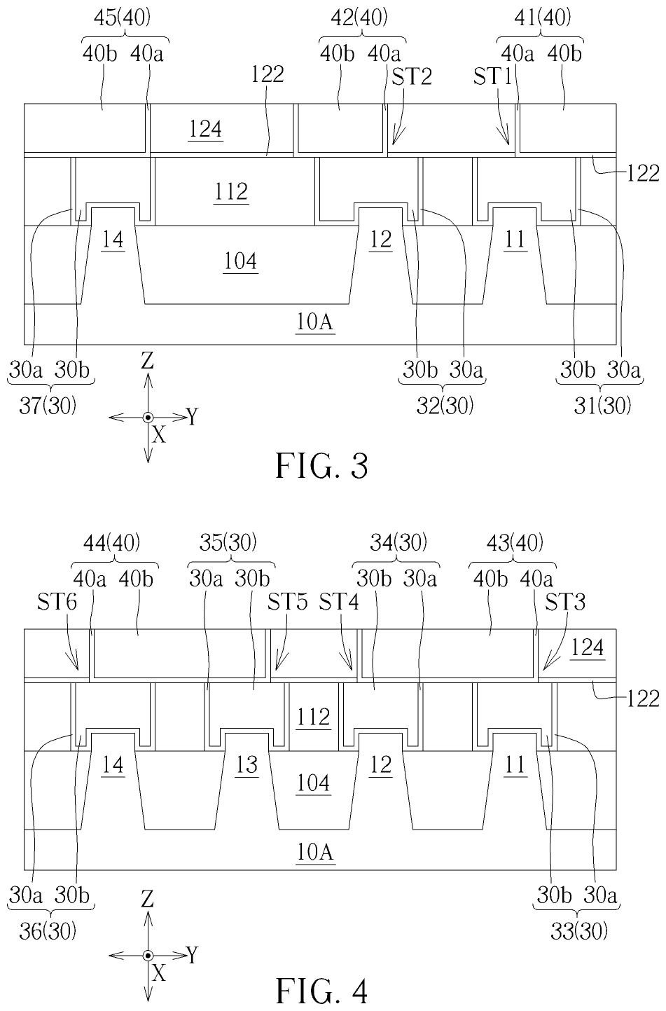

Please return to FIG. 2 and also refer to FIG. 3 and FIG. 4. FIG. 3 shows a cross-sectional view of the SRAM along line AA′ in FIG. 2. FIG. 4 shows a cross-sectional view of the SRAM along line BB′ in FIG. 2. In detail, the first lower contact 31, the second lower contact 32, the third lower contact 33, and the fourth lower contact 34 respectively have a first edge (namely 31a, 32a, 33a, and 34a) between the first active region 11 and the second active region 12 and a second edge (namely 31b, 32b, 33b, and 34b) opposite to the first edge. The sixth lower contact 36 and the seventh lower contact 37 respectively include a third edge (namely 36a and 37a) located between the third active region 13 and the fourth active region 14, and a fourth edge (namely 36b and 37b) opposite to the third edge.

As previously mentioned, the first lower contact 31 and the third lower contact 33 are defined by the same T-shaped slot opening 116a, wherein the first edge 31a and the first edge 33a are defined by the straight edge of the slot opening 116a, the second edge 31b is defined by the convex edge of the protruding portion of the slot opening 116a, and the second edge 33b is defined by the flat edges aside the protruding portion. Therefore, the first edge 31a and the first edge 33a are aligned with each other along the first direction X (aligned along the DD′ line as shown in FIG. 2), while the second edge 31b and the second edge 33b are not aligned in the first direction X. The second lower contact 32 and the fourth lower contact 34 are defined by another T-shaped slot opening 116a, wherein the first edge 32a and the first edge 34a are defined by the straight edge of the slot opening 116a, the second edge 32b is defined by the of the protruding portion of the slot opening 116a, and the second edge 34b is defined by the flat edges aside the protruding portion. Therefore, the first edge 32a and the first edge 34a are aligned with each other along the first direction X (aligned along the CC′ line as shown in FIG. 2), while the second edge 32b and the second edge 34b are not aligned in the first direction X. The distance between the first edge 31a and the second edge 31b of the first lower contact 31 is larger than the distance between the first edge 33a and the second edge 33b of the third lower contact 33. The distance between the first edge 32a and the second edge 32b of the second lower contact 32 is larger than the distance between the first edge 34a and the second edge 34b of the fourth lower contact 34.

The sixth lower contact 36 and the seventh lower contact 37 are defined by the same slot opening 116a. The third edge 36a and the third edge 37a are defined by the straight edge of the slot opening 116a, and are aligned with each other along the first direction X (aligned along the EE′ line as shown in FIG. 2). The fourth edge 36b and the fourth edge 37b are defined by another straight edge of the slot opening 116a, and are aligned with each other along the first direction X.

The first upper contact 41 is disposed on the first lower contact 31 and offset in the direction away from the first edge 31a of the first lower contact 31. The second upper contact 42 is disposed on the second lower contact 32 and offset in the direction away from the first edge 32a of the second lower contact 32. As shown in FIG. 3, the sidewall of the first upper contact 41 and the top surface of the first lower contact 31 form a first step portion ST1. The sidewall of the second upper contact 42 and the top surface of the second lower contact 32 form a second step portion ST2. The first step portion ST1 and the second step portion ST2 are opposite to each other.

In some embodiments, the end portions of the third upper contact 43 and the fourth upper contact 44 may be pulled back from the second edges of the lower contacts to increase the spacing therebetween for a larger process margin. Accordingly, as shown in FIG. 4, a sidewall of the third upper contact 43 and the top surface of the third lower contact 33 form a third step portion ST3, and the other sidewall of the third upper contact 43 and the top surface of the fourth lower contact 34 form a fourth step portion ST4. Likewise, a sidewall of the fourth upper contact 44 and the top surface of the fifth lower contact 35 form a fifth step portion ST5, and the other sidewall of the fourth upper contact 44 and the top surface of the sixth lower contact 36 form a sixth step portion ST6. The step width (the width of the top surface of the lower contact exposed from the upper contact) of each of the step portions ST1, ST2, ST3, ST4, ST5, and ST6 may be adjusted based on design requirements.

The present invention uses a novel T-shaped slot opening 116a in a multiple patterning process to define the first lower contact 31 and the second lower contact 32 to increase the length of the first lower contact 31 and the second lower contact 32 in the second direction Y, which may ensure sufficient contact areas and connecting quality between the first lower contact 31 and the first upper contact 41 as well as between the second lower contact 32 and the second upper contact 42 while first step portion ST1 and second step portion ST2 are formed.

In summary, the SRAM and the method for forming the SRAM provided by the present invention, having active region contact structures respectively composed of a lower contact and an upper contact stacked on the lower contact, may provide a larger layout design flexibility to resolve bottleneck in device miniaturization development and improve the process margin.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory (SRAM), comprising:
a substrate comprising a first active region and a second active region parallel to the first active region;
a first gate structure crossing the first active region and the second active region;
a first lower contact and a second lower contact respectively on the first active region and the second active region at a first side of the first gate structure; and
a third lower contact and a fourth lower contact respectively on the first active region and the second active region at a second side of the first gate structure, wherein in a top view, the first lower contact, the second lower contact, the third lower contact and the fourth lower contact respectively have a first edge between the first active region and the second active region and a second edge opposite to the first edge, wherein the first edge of the first lower contact is aligned to the first edge of the third lower contact, the first edge of the second lower contact is aligned to the first edge of the fourth lower contact, the second edge of the first lower contact is not aligned to the second edge of the third lower contact, and the second edge of the second lower contact is not aligned to the second edge of the fourth lower contact.

2. The SRAM according to claim 1, wherein a top surface of the first lower contact, a top surface of the second lower contact, a top surface of the third lower contact and a top surface of the fourth lower contact are flush with a top surface of the first gate structure.

3. The SRAM according to claim 1, further comprising:
a first upper contact on the first lower contact and offset in a direction away from the first edge of the first lower contact; and
a second upper contact on the second lower contact and offset in a direction away from the first edge of the second lower contact.

4. The SRAM according to claim 3, wherein in a cross-sectional view, a sidewall of the first upper contact and a top surface of the first lower contact comprise a first step portion, a sidewall of the second upper contact and a top surface of the second lower contact comprise a second step portion, and the first step portion is opposite to the second step portion.

5. The SRAM according to claim 1, further comprising a third upper contact on the third lower contact and the fourth lower contact to electrically connect the third lower contact and the fourth lower contact.

6. The SRAM according to claim 5, wherein in a cross-sectional view, a sidewall of the third upper contact and a top surface of the third lower contact comprises a third step portion, another sidewall of the third upper contact and a top surface of the fourth lower contact comprises a fourth step portion.

7. The SRAM according to claim 1, further comprising:
a third active region and a fourth active region parallel to the second active region, wherein the third active region is between the second active region and the fourth active region;
a second gate structure crossing the third active region and the fourth active region;
a fifth lower contact and a sixth lower contact respectively on the third active region and the fourth active region at a side of the second gate structure next to the first gate structure; and
a fourth upper contact on the fifth lower contact and the sixth lower contact to electrically connect the fifth lower contact and the sixth lower contact.

8. The SRAM according to claim 7, wherein in a cross-sectional view, a sidewall of the fourth upper contact and a top surface of the fifth lower contact comprises a fifth step portion, another sidewall of the fourth upper contact and a top surface of the sixth lower contact comprises a sixth step portion.

9. The SRAM according to claim 7, further comprising:
a third gate structure aligned with the first gate structure and crossing the fourth active region, wherein the sixth lower contact is between the second gate structure and the third gate structure; and
a seventh lower contact on the fourth active region at a side of the third gate structure opposite to the sixth lower contact, wherein the sixth lower contact and the seventh lower contact respectively have a third edge between the third active region and the fourth active region and a fourth edge opposite to the third edge, wherein the third edge and the fourth edge of the sixth lower contact are aligned to the third edge and the fourth edge of the seventh lower contact, respectively.

10. The SRAM according to claim 1, wherein in the top view, a distance between the first edge and the second edge of the first lower contact is larger than a distance between the first edge and the second edge of the third lower contact, a distance between the first edge and the second edge of the second lower contact is larger than a distance between the first edge and the second edge of the fourth lower contact.

11. A method for forming a static random access memory (SRAM), comprising:
providing a substrate comprising a plurality of active regions arranged parallel to each other;
forming a lower interlayer dielectric layer on the substrate and a plurality of gate structures in the lower interlayer dielectric layer and crossing the active regions;
forming a first patterned mask on the lower interlayer dielectric layer, the first patterned mask comprising a plurality of slot openings corresponding to the active regions;
forming a second patterned mask on the first patterned mask, the second patterned mask comprising a plurality of stripe patterns corresponding to the gate structures;
using the first patterned mask and the stripe patterns as an etching mask to etch the lower interlayer dielectric layer, thereby forming a plurality of lower contact openings that expose portions of the active regions; and
forming lower contacts in the lower contact openings.

12. The method for forming a SRAM according to claim 11, wherein top surfaces of the lower contacts are flush with top surfaces of the gate structures.

13. The method for forming a SRAM according to claim 11, wherein the slot openings have different shapes.

14. The method for forming a SRAM according to claim 11, wherein the slot openings have different sizes.

15. The method for forming a SRAM according to claim 11, wherein the step of forming the first patterned mask comprises:
using a first photo mask to define the slot opening corresponding to odd rows of the active regions; and
using a second photo mask to define the slot opening corresponding to even rows of the active regions.

16. The method for forming a SRAM according to claim 11, wherein the step of forming the second patterned mask comprises:
using a third photo mask to define the stripe patterns corresponding to odd columns of the gate structures; and
using a fourth photo mask to define the stripe patterns corresponding to even columns of the gate structures.

17. The method for forming a SRAM according to claim 16, wherein the stripe patterns corresponding to the odd columns of the gate structures and the stripe patterns corresponding to the even columns of the gate structures are made of different materials.

18. The method for forming a SRAM according to claim 11, wherein the first patterned mask and the second patterned mask are made of different materials.

19. The method for forming a SRAM according to claim 11, further comprising:
forming an upper interlayer dielectric layer on the lower interlayer dielectric layer; and
forming upper contacts in the upper interlayer dielectric layer, respectively on the lower contacts.

20. The method for forming a SRAM according to claim 19, wherein some of the upper contacts are offset from the lower contacts to form step portions.
